(19) United States
(12) Patent Application Publication
(10) Pub. No.: US 2026/0353871 A1
(43) Pub. Date: Nov. 5, 2026

(54) P-SIDE UP MICROLED STRUCTURE

(71) Applicant: Lumileds LLC, San Jose, CA (US)

(72) Inventors: Antonio Lopez Julia, Eindhoven (NL); Erik William Young, San Jose, CA (US)

(21) Appl. No.: 19/487,976

(22) PCT Filed: May 20, 2024
(86) PCT No.: PCT/US2024/030176

§ 371 Date: Nov. 25, 2025

Related U.S. Application Data
(60) Provisional application No. 63/469,974, filed on May 31, 2023.

(51) Int. Cl. H10H 20/819; H10H 29/01; H10H 29/39; H10H 29/41

(52) U.S. Cl. CPC H10H 20/819; H10H 29/011; H10H 29/032; H10H 29/39; H10H 29/41

(57) ABSTRACT

A light emitting diode (LED) array and method of fabricating the LED array are described. The LED array has trapezoidal pixels of microLEDs. Each pixel contains an epitaxial LED structure with n-type and p-type semiconductor layers, and an active region configured to emit light through the p-type layer. Sidewalls of the pixels extend at an angle of about 20° from a growth direction of the layers. A transparent conducting oxide (TCO) layer is on the p-type layer and a patterned periodic nanostructure is on the TCO layer.

### PRIORITY CLAIM

This application claims the benefit of priority to U.S. Provisional Patent Application Ser. No. 63/469,974, filed May 31, 2023, which is incorporated herein by reference in its entirety.

### FIELD OF THE DISCLOSURE

The present disclosure relates to light emitting diode (LED) arrays. In particular, embodiments are directed to microLED architectures.

### BACKGROUND OF THE DISCLOSURE

Due to the small size of microLEDs, microLED architectures can suffer from a variety of deficiencies, including those related to light extraction efficiency (ExE), internal quantum efficiency (IQE) droop and non-radiative surface recombination loss, poor angular directionality, and optical losses at sidewalls.

### BRIEF DESCRIPTION OF THE DRAWINGS

FIG. 1 shows an illumination apparatus, in accordance with some examples.

FIG. 2A illustrates a monolithic LED pixel array, in accordance with some examples.

FIG. 2B illustrates a single pixel of the monolithic LED pixel array of FIG. 2A, in accordance with some examples.

FIG. 2C illustrates an alternative single pixel of the monolithic LED pixel array of FIG. 2A, in accordance with some examples.

FIG. 2D illustrates a different single pixel of the monolithic LED pixel array of FIG. 2A, in accordance with some examples.

FIGS. 3A-3N illustrate a fabrication method for a p-side up microLED structure, in accordance with some examples.

FIGS. 4A-4O illustrate another fabrication method for a p-side up microLED structure, in accordance with some examples.

FIG. 5 shows a simulated performance comparison between LED structures.

FIG. 6 illustrates an example of a general device in accordance with some embodiments.

FIG. 7 illustrates an example lighting system, according to some embodiments.

FIG. 8 illustrates an example hardware arrangement for implementing the above disclosed subject matter, according to some embodiments.

FIG. 9 shows a block diagram of an example of a system, according to some embodiments.

FIG. 10 illustrates an example method of fabricating an illumination device, according to some embodiments.

FIG. 11 illustrates a top plan view of an example array suitable for implementing embodiments described herein.

### DETAILED DESCRIPTION

LED structures may suffer from various shortcomings, which are exacerbated when microLED structures are formed. To provide a more efficient microLED, a p-side up structure may be used that benefits from reduced sidewall optical losses and highly directional emission.

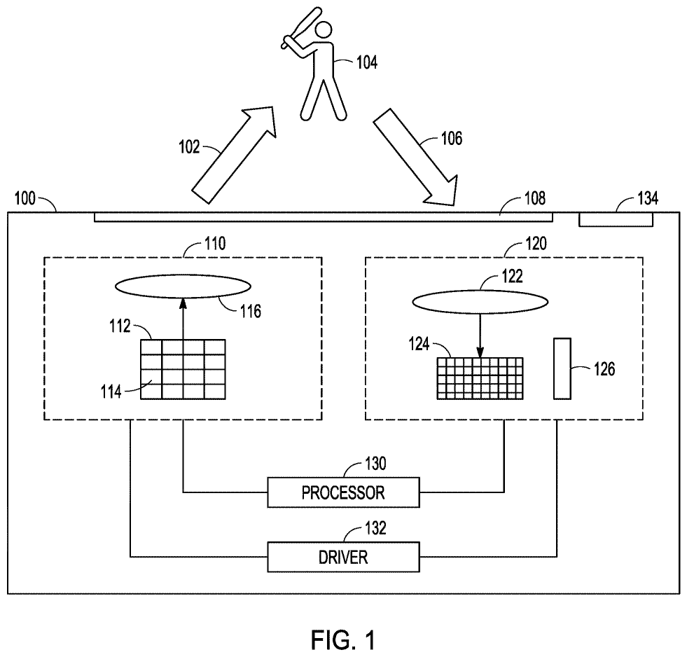

FIG. 1 shows an illumination apparatus 100, in accordance with some examples. The illumination apparatus 100 may be, for example, a smart phone or standalone camera. Other embodiments, which may contain some or all of the components shown in FIG. 1 (as well as additional components not shown), include displays, automotive adaptive headlights, augmented-, virtual-, mix-reality (AR/VR/MR) headsets, smart glasses and displays for mobile phones, smart watches, monitors, and TVs. The illumination apparatus 100 may include both a light source 110 and a camera 120. The camera 120 may capture an image of a scene 104 during an exposure duration of the camera 120, whether or not the scene 104 is illuminated by the light source 110. A processor 130 may be used to control various functions of the light source 110 and the camera 120, including whether or not a shutter is open in an opening 108 of a housing of the illumination apparatus 100.

The opening 108 may be a single opening as shown in FIG. 1 or may include multiple separate openings. Similarly, the shutter may be a single shutter that covers both the light source 110 and the camera 120 or may include multiple separate shutters that covers only one of the light source 110 or the camera 120 and are individually controllable by the processor 130.

The illumination apparatus 100 may include one or more microLED arrays 112. Each of the one or more microLED arrays 112 may include a plurality of microLEDs 114 that may produce light during at least a portion of the exposure duration of the camera 120. Each of the one or more microLED arrays 112 may contain segmented ones of the plurality of microLEDs 114 in which the microLEDs 114 are divided into a grid of light emitting areas (the microLED 114) and non-light emitting areas (between the microLEDs 114).

Each of the microLEDs 114 may be formed from one or more inorganic materials (e.g., binary compounds such as gallium arsenide (GaAs), ternary compounds such as aluminum gallium arsenide (AlGaAs), quaternary compounds such as indium gallium phosphide (InGaAsP), gallium nitride (GaN), or other suitable materials), usually either III-V materials (defined by columns of the Periodic Table) or II-VI materials. Each of the microLEDs 114 may emit light in the visible spectrum (about 400 nm to about 800 nm) or may also emit light in the infrared spectrum (above about 800 nm). In some embodiments, one or more other layers, such as a phosphor layer may be disposed on each of the one or more microLED arrays 112 to convert the light from the microLEDs 114 into white (or another color) light. MicroLEDs 114 in a particular microLED array 112 that emit light in the infrared spectrum may be, for example, interspersed with microLEDs 114 may emit light in the visible spectrum, or each type of microLED (visible emitter/infrared emitter) may be disposed on different sections of the particular microLED array 112. Alternatively, each microLED array 112 may only emit light in either the visible spectrum or the infrared spectrum; separate (one or more) microLED arrays may be used to emit light in the infrared spectrum, each of the individual ones of the microLED arrays 112, microLEDs 114 and/or microLED segments controllable by the processor 130.

Each of the one or more microLED arrays 112 may be include thousands to millions of microscopic ones of the plurality of microLEDs 114 that emit light and that may be individually controlled or controlled in groups of pixels (e.g., 5×5 groups of pixels). The microLEDs are small (e.g., <0.01 mm on a side) and may provide monochromatic or multi-chromatic light, typically red, green, or yellow using inorganic semiconductor material such as that indicated above.

The light source 110 may include at least one lens 116 and/or other optical elements such as reflectors. The lens 116 and/or other optical elements may direct the light emitted by the one or more microLED arrays 112 toward the scene 104 as illumination 102.

The camera 120 may sense light at least the wavelength or wavelengths emitted by the one or more microLED arrays 112. Similar to the light source 110, the camera 120 may include optics (e.g., at least one camera lens 122) that are able to collect reflected light 106 of the illumination 102 that is reflected from and/or emitted by the scene 104. The camera lens 122 may direct the reflected light 106 onto a multi-pixel sensor 124 (also referred to as a light sensor) to form an image of the scene 104 on the multi-pixel sensor 124.

The processor 130 may receive a data signal that represents the image of the scene 104. The processor 130 may additionally control and drive the microLEDs 114 in the one or more microLED arrays 112 via one or more drivers 132. For example, the processor 130 may optionally control one or more microLEDs 114 in the one or more microLED arrays 112 independent of another one or more microLEDs 114 in the one or more microLED arrays 112, so as to illuminate the scene in a specified manner.

In addition, one or more detectors 126 may be incorporated in the camera 120. In other embodiments, instead of being incorporated in the camera 120, the one or more detectors 126 may be incorporated in one or more different areas, such as the light source 110 or elsewhere close to the camera 120. The one or more detectors 126 may include multiple different sensors to sense visible and/or infrared light (e.g., from the scene 104), and may further sense the ambient light and/or variations/flicker in the ambient light in addition to reception of the reflected light from the microLEDs 114. The multi-pixel sensor 124 of the camera 120 may be of higher resolution than the sensors of the one or more detectors 126 to obtain an image of the scene with a desired resolution.

The sensors of the one or more detectors 126 may have one or more segments (that are able to sense the same wavelength/range of wavelengths or different wavelength/range of wavelengths), similar to the microLED arrays 112. In some embodiments, if multiple detectors are used, one or more of the detectors may detect visible wavelengths and one or more of the detectors may detect infrared wavelengths; like the one or more microLED arrays 112, the one or more detectors 126 may be individually controllable by the processor 130.

In some embodiments, instead of, or in addition to, being provided in the camera 120, one or more of the sensors of the one or more detectors 126 may be provided in the light source 110. In some embodiments, the light source 110 and the camera 120 may be integrated in a single module, while in other embodiments, the light source 110 and the camera 120 may be separate modules that are disposed on a PCB. In other embodiments, the light source 110 and the camera 120 may be attached to different PCBs-for example, as the camera 120 may be thicker than the light source 110, which may result in design issues if the light source 110 and the camera 120 are attached to the same PCB. In the latter embodiment, multiple openings may be present in the housing at least one of which may be eliminated with the use of an integrated version of the light source 110 and camera 120.

The microLEDs 114 may be driven in an analog or digital manner, i.e., using a direct current (DC) driver or pulse width modulation (PWM) signals (e.g., in the latter case, controlling PWM duty cycles and/or turn-on times. As shown, one or more drivers 132 may be used to drive the microLEDs 114 in the one or more microLED arrays 112, as well as other components, such as the actuators.

The illumination apparatus 100 may also include an input device 134, for example, a user-activated input device such as a button that is depressed to take a picture. The light source 110 and camera 120 may be disposed in a single housing.

The illumination apparatus 100 shown in FIG. 1, microLEDs can be used to form different types of displays, microLED matrices and light engines including automotive adaptive headlights, augmented-, virtual-, mix-reality (AR/VR/MR) headsets, smart glasses and displays for mobile phones, smart watches, monitors and TVs. The individual microLED pixels in these architectures may, as above, have an area of few square millimeters down to few square micrometers depending on the matrix or display size and pixel-per-inch requirements. One common approach is to create a monolithic array of microLED pixels on an epitaxial wafer and later transfer and hybridize the microLED arrays to a backplane to allow individual control of the pixels, as described in more detail below.

MicroLEDs may be formed by combining n- and p-type semiconductors (e.g., III-V semiconductors above) on a substrate of sapphire aluminum oxide (Al₂O₃) or silicon carbide (SiC), among others. In particular, various layers are deposited and processed on the substrate during fabrication of the microLED. The surface of the substrate may be pretreated to anneal, etch, polish, etc. the surface prior to deposition of the various layers.

In general, the various LED layers may be fabricated using epitaxial semiconductor deposition (e.g., by metal organic chemical vapor deposition) to deposit one or more semiconductor layers, metal deposition (e.g., by sputtering), oxide growth, as well as etching, liftoff, and cleaning, among other operations. The substrate may be removed from the LED structure after fabrication and after connection to contacts on a backplane via metal bonding such as via wire or ball bonding. The backplane may be a printed circuit board or wafer containing integrated circuits (ICs), such as a CMOS IC wafer. The semiconductor deposition operations may be used to create an LED with an active region in which electron-hole recombination occurs and the light from the LED is generated. The active region may be, for example, one or more quantum wells. Metal contacts may be used to drive provide current to the n-and p-type semiconductors from the ICs (such as drivers) of the backplane on which the LED is disposed. Methods of depositing materials, layers, and thin films may include, for example: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Inorganic LEDs and LED architectures have been widely used to create different types of devices. The individual LED pixels in these architectures may have an area of few square mm down to few square um depending on the LED matrix or display size and pixel per inch characteristics. One approach is to create a monolithic array of LED pixels on an epitaxial wafer and later transfer and hybridize the LED arrays to a backplane to control individual pixels. One embodiment of such monolithic arrays uses metal (e.g., aluminum (Al)- or silver (Ag)-based) side-contacts. These contacts may serve as the electrical cathode for each pixel and also provide reflective sidewalls between the pixels to reduce light scattering and propagation in lateral directions.

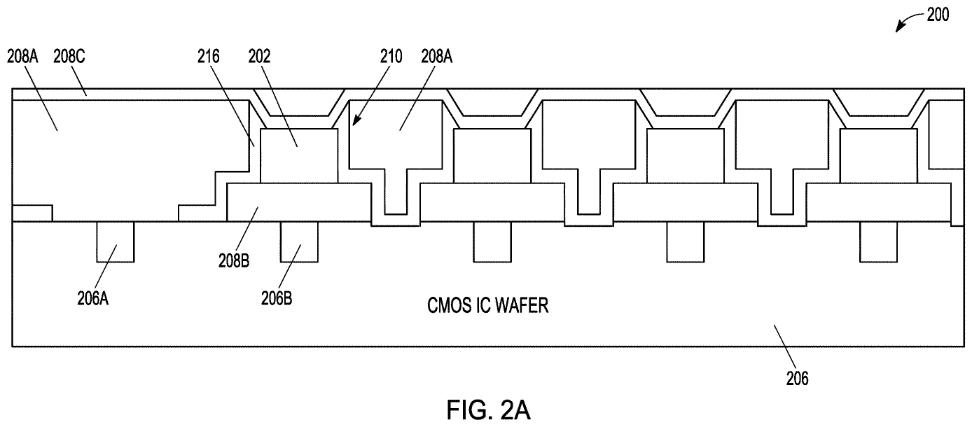

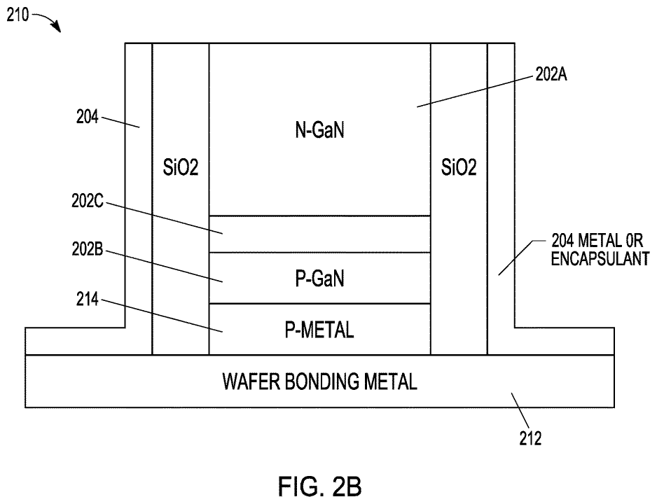

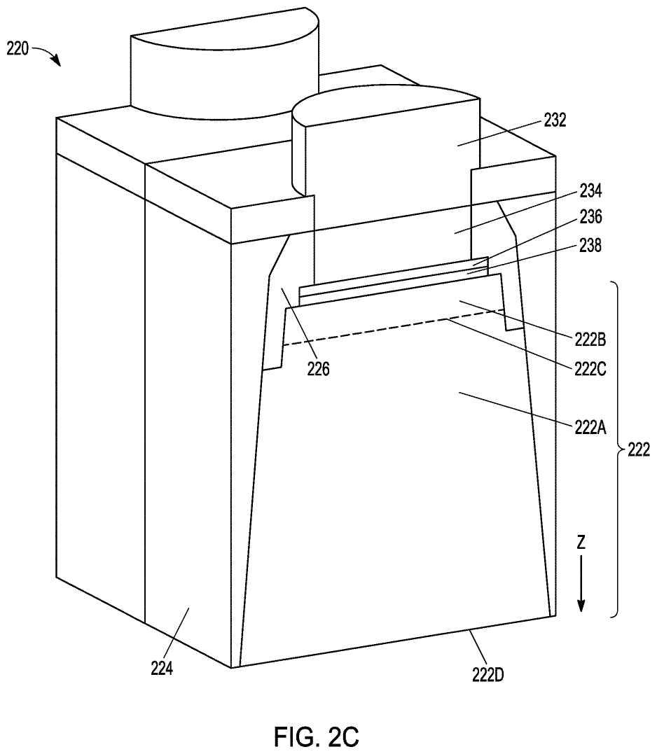

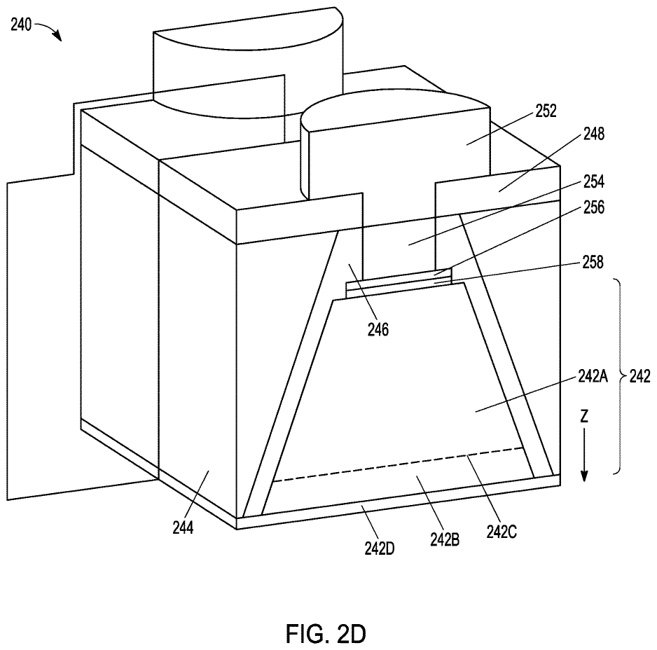

FIG. 2A illustrates a monolithic LED pixel array, in accordance with some examples. FIG. 2B illustrates a single pixel of the monolithic LED pixel array of FIG. 2A, in accordance with some examples. As shown in the monolithic LED pixel array 200 of FIG. 2A, contains pixels 210 each having a sidewall and a semiconductor stack 202 (shown as a mesa structure). A dielectric material 216 surrounds the sidewall of each of the pixels 210, and n-contact material 208a is positioned between adjacent pixels on the dielectric material 216. A common cathode 208c is in electrical contact with the n-type layer of the semiconductor stack 202 and the n-contact material 208a. An anode 208b is in contact with each p-type layer of the semiconductor stack 202 and a corresponding anode 206b of a backplane 206. The n-contact material 208a is in contact with another contact 206a of the backplane 206. An upper edge of each semiconductor stack 202 may be offset from an upper edges of the n-contact material 208a and common cathode 208c.

The dielectric material 216 may act as reflective sidewalls adjacent to the semiconductor stack 202. The anode 208b may contact the n-type layers of the semiconductor stack 202 and act as a current spreading layer.

As shown in more detail in FIG. 2B, the semiconductor stack 202 forming the LED may be, as above, GaN. In particular, the semiconductor stack 202 may have a height H and a lateral distance D and may include an active region 202c sandwiched between n-type semiconductor 202a and p-type semiconductor 202b. In some embodiments, the metal side-contacts 204 may be coupled to the n-type semiconductor 202a to drive the n-type semiconductor 202a and, while a metal contact (p-metal 214 or cathode contact) is coupled to the p-type semiconductor 202b. The metal side-contacts 204 may be isolated from the p-type semiconductor 202b and the active region 202c by a dielectric material 216. The dielectric material 216 may be formed, for example, by silicon oxide. Wafer bonding metal 212 may be configured to provide contact to the p-metal 214 and metal side-contacts 204. The p-metal 214 and metal side-contacts 204 may be formed from aluminum or other material(s) substantially reflective (e.g., greater than about 99% reflectivity at a normal angle of incidence) to light emitted by the active region 202c. The p-metal 214 and metal side-contacts 204 may be formed from the same metal or different metals. In these architectures, as above the original substrate (e.g., Sapphire, Silicon) may be removed (e.g., by liftoff) after the LED array is integrated with a backplane 206 (that contains a driver and controller, among others) from the opposite side of the pixels 210 as the backplane 206. This offers multiple advantages such as enhanced light extraction and beam profiling. Although the p-metal 214 is shown in FIG. 2B as being the same width as the various layers of the semiconductor stack 202, in other embodiments, the p-metal 214 may be larger than the various layers of the semiconductor stack 202 (which may permit contact between the p-metal 214 and the p-type semiconductor 202b).

In these architectures, the substrate (e.g., Sapphire, Silicon) on which the epitaxial semiconductors are grown may be removed after the LED array is integrated with the backplane driver+controller. This offers multiple advantages such as enhanced light extraction and beam profiling. One approach to remove a Sapphire substrate is by a laser lift-off (LLO) process in which a laser beam (ultraviolet (UV) laser in the case of a Sapphire substrate) is used to detach the substrate from the epitaxial layers (in this case, LED arrays grown on the substrate).

In large LED emitters (non-microLED emitters), a patterned Sapphire substrate (PSS) may be used; that is the substrate may be patterned with micron scale features such that, after LLO, the exposed surface (e.g., gallium nitride (GaN)) is textured. This may facilitate light extraction from the resulting LED structure. However, in microLED structures, such patterning may not be possible since the PSS features dimensions are too large relative to the pixel size. Therefore, the epitaxial semiconductor layers may be grown on a planar epitaxial substrate. Such small pixel emitters with planar extraction surfaces, unfortunately, suffer from poor extraction efficiency and wide angular radiation profiles. In order to reduce or minimize this extraction efficiency penalty, the trench sidewalls may be fabricated with highly oblique angles (e.g., more than 30° from normal). The resulting trapezoidal shape can significantly enhance light outcoupling. However, in such arrangement, a mesa formation with slated walls can etch away a large portion of the active region that generates the light, thus worsening surface recombination and IQE droop-related losses.

FIG. 2C illustrates a single pixel of the monolithic LED pixel array of FIG. 2A, in accordance with some examples. The materials of the various layers in FIG. 2C may be the same as those in FIG. 2B. As shown in FIG. 2C, the pixel 220 may include a semiconductor 222 with an active region 222c sandwiched between n-type semiconductor 222a and p-type semiconductor 222b. Metal side-contacts 224 may be coupled to the n-type semiconductor 222a to drive the n-type semiconductor 222a and, while a metal contact (p-metal 234) is coupled to the p-type semiconductor 222b. The metal side-contacts 224 may be isolated from the p-type semiconductor 222b and the active region 222c by an oxide layer 226. A bonding pad 232 may provide contact to p-metal 234 that provides electrical connection to the p-type semiconductor 222b through a guardsheet 236 and reflector metal 238. The pixel 220 in FIG. 2C may have sidewalls that are somewhat angled (e.g., a few degrees) with respect to the growth direction (shown as the z direction in FIG. 2C and which is perpendicular to the emitting surface 222d of the n-type semiconductor 222a).

Instead of the structure shown in FIG. 2C, the above p-side up structure may be used. FIG. 2D illustrates a different single pixel of a monolithic LED pixel array similar to that of FIG. 2A, in accordance with some examples. The materials of the various layers in FIG. 2C may be the same as those in FIG. 2B. As shown in FIG. 2D, the pixel 240 may include a semiconductor 242 with an active region 242c sandwiched between n-type semiconductor 242a and p-type semiconductor 242b. The p-type semiconductor 242b may be a pGaN layer having a range between about 50 nm and about 180 nm. The active region 242c may be formed, for example, from a multiple quantum well (MQW) structure. The semiconductor 242 may be isolated by one or more dielectric layers 246, such as SiO2 or a multi-layer insulating structure that forms a Bragg reflector for example, that form the mesa sidewalls.

An anode contact 254 (or n-metal) may be plated and then chemical-mechanically planarized (CMP) to provide electrical contact to the n-type semiconductor 242a (e.g., nGaN). A metal bonding pad 252 may provide electrical contact to the anode contact 254 to drive the n-type semiconductor 242a. The n-type semiconductor 242a may be electrically connected to the metal bonding pad 252 through the anode contact 254, a metal guardsheet 256, and reflector metal 258. The reflector metal 258 may be formed from one or more layers that are configured to reflect light emitted by the active region 242c back towards a transparent conducting oxide (TCO) layer 242d (such as indium tin oxide (ITO)) on an emission surface of the semiconductor 242. The metal guardsheet 256 may be used to protect the reflector metal 258 during subsequent processing to form additional metal and/or dielectric layers (such as the anode contact 254 and the dielectric layers 246).

Metal side contacts 244 may be isolated from the p-type semiconductor 242b and the active region 242c by the dielectric layers 246 and from the metal bonding pad 252 by another dielectric layer 248 formed on the anode contact 254 after planarization of the anode contact 254. The TCO layer 242d may extend to contact the metal side contacts 244. The other dielectric layer 248 may be formed from insulating material similar to the dielectric layers 246. The metal side contacts 244 and the anode contact 254 may be formed from one or more layers such as aluminum (Al), titanium tungsten (TiW), and/or copper (Cu). The metal side contacts 244 may be electrically coupled to the TCO layer 242d.

The semiconductor 242 in FIG. 2D may have sidewalls that are substantially angled with respect to the growth direction (e.g., in the range of about 15° to about 35°). The angles of the sidewalls of the semiconductor 242 in the pixel 240 may be more than that of the semiconductor 222 in the pixel 220 in FIG. 2C. The overall size of the pixel 240 may be about 5 μm (each side—i.e., an area of about 25 μm²), with about a 3 μm thick (thinned) epitaxial layer and 20° sidewalls. The sidewalls of the semiconductor 242 may be insulated by the dielectric layers 246.

If the semiconductor is grown on an unpatterned substrate, the emitting surface remains unpatterned after the fabrication is completed. This can lead to poor ExE and unfavorably wide angular radiation emission, which is exacerbated for the case of small pixels (e.g., microLEDs) with steep trench sidewall angles. The extraction efficiency increases with increasing angles from the semiconductor growth direction (forming the trapezoidal shape) due at least in part due to the increased active region area. In addition to the use of metal trench sidewalls to increase light emission from the pixel, thick epitaxial layers (relative to pixel lateral size) lead to increased metal sidewall areas, and thus steeper trench sidewalls avoid reducing the area of MQWs used to reduce or minimize droop and surface recombination currents. That is, increasing the sidewall angles results in a reduction in the size of the top metal contact to the semiconductor and thus a reduction in electrical efficiency.

Compared to this, the semiconductor 242 may have a relatively thin set of epitaxial layers (relative to pixel lateral size), thus reducing excessive (suboptimal) aspect ratio in small pixels. As the dielectric layers 246 are formed from a dielectric (e.g., oxide), light interaction with metal at the trench may be reduced. In addition, among others, as above a TCO layer may replace a lateral n-contact at the dielectric layers 246, the mesa sidewall angle may increase light outcoupling and directionality, and pGaN up to avoid reduction of MQW area caused by slanted mesa-side walls. The dielectric layers 246 may extend at an angle of, for example, about 20° (i.e., within about 15° to about 35°) from the z direction. Note that the term “about x” and similar terms (e.g., substantially) as used herein, unless otherwise indicated, may be understood to be within 10% of x or otherwise within a range known to one of skill in the art to be within tolerance of the quantity or quality described.

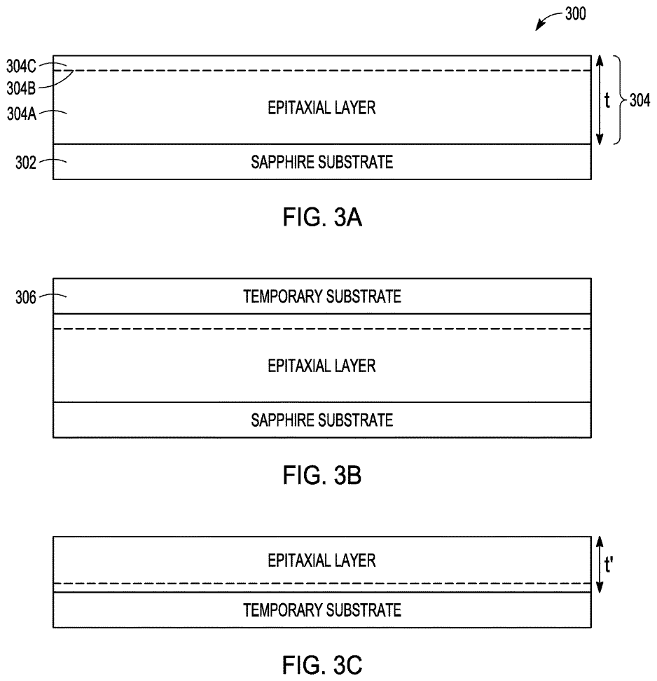

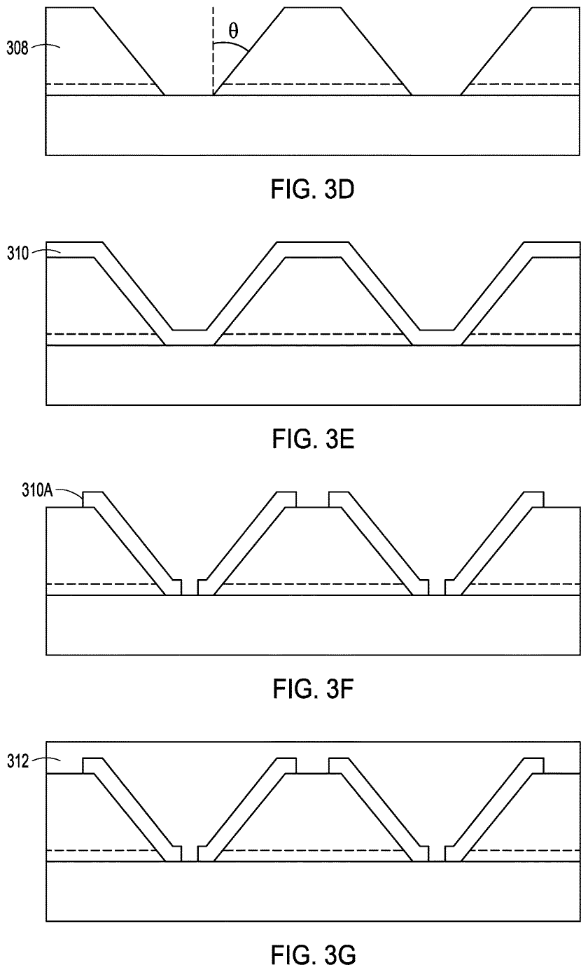

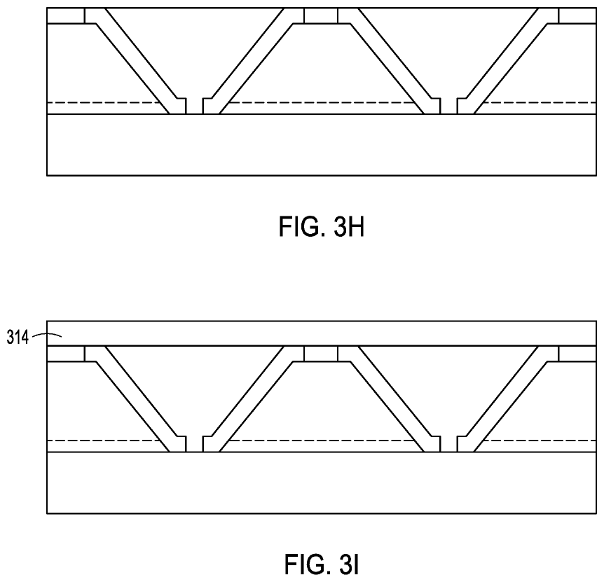

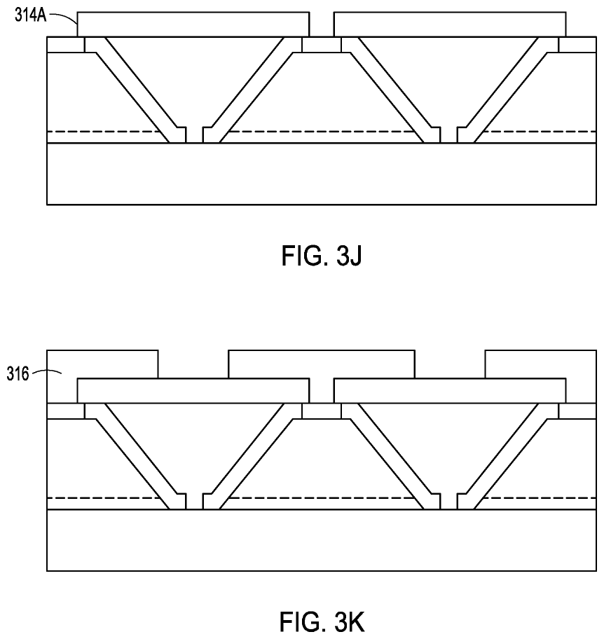

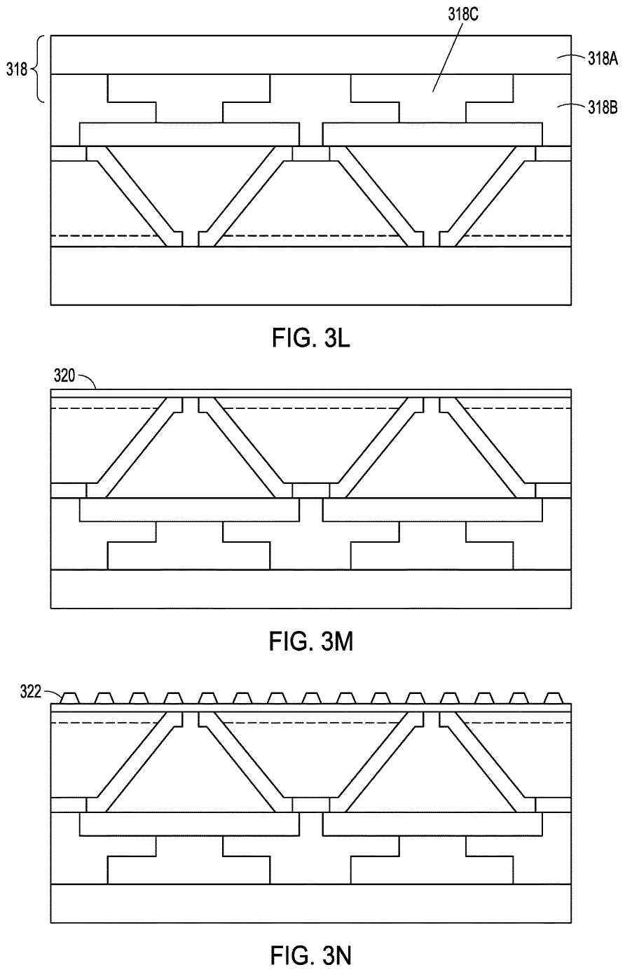

FIGS. 3A-3N illustrate a fabrication method for a p-side up microLED structure, in accordance with some examples. FIGS. 3A-3N illustrate cross-sectional views of a partial portion of the overall array (or segmented structure). FIG. 3A illustrates an initial structure 300 that includes an epitaxial layer 304 of thickness t (e.g., about 6 μm) grown on a Sapphire substrate 302. The epitaxial layer 304 may include a relatively thicker n-type semiconductor layer 304a and a relatively thinner p-type semiconductor layer 304c surrounding a MQW active layer 304b. Other layers may be present but are not shown for convenience.

In FIG. 3B, a temporary substrate 306 is attached to the initial structure 300 using an adhesive layer or an oxide-oxide bond. The temporary substrate 306 may be formed from any material sufficient to support the initial structure 300 during subsequent processing steps, such as glass, Sapphire, or polycrystalline material.

In FIG. 3C, the Sapphire substrate 302 is removed and the n-type semiconductor layer 304a is etched such that the remaining epitaxial layer 304 has a thickness t′ significantly less than the original thickness (e.g., about 1 μm to about 4 μm from the original 6 μm above). In embodiments in which the doping of the n-type semiconductor layer varies with depth, the etching may expose a more heavily n-doped (n++) semiconductor layer (or portion of the semiconductor layer).

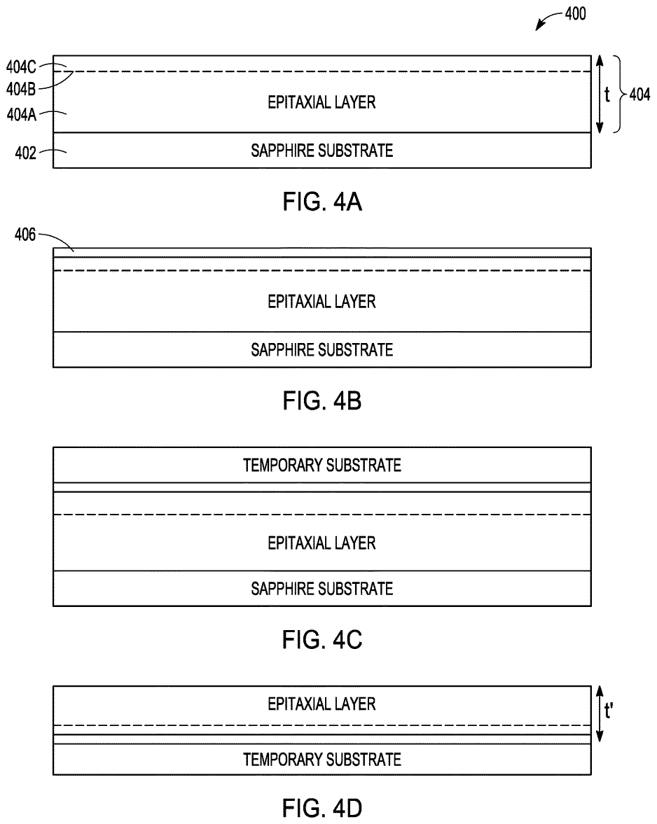

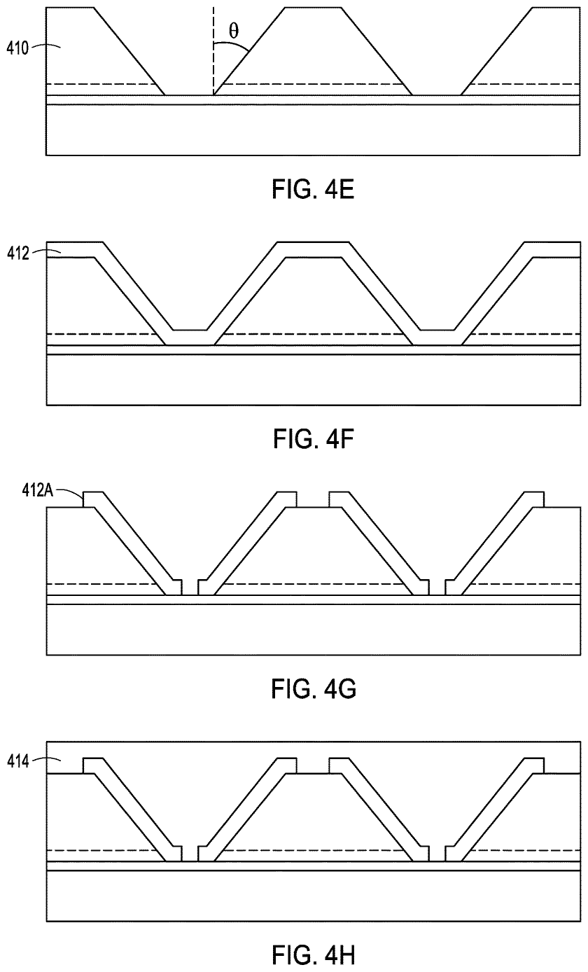

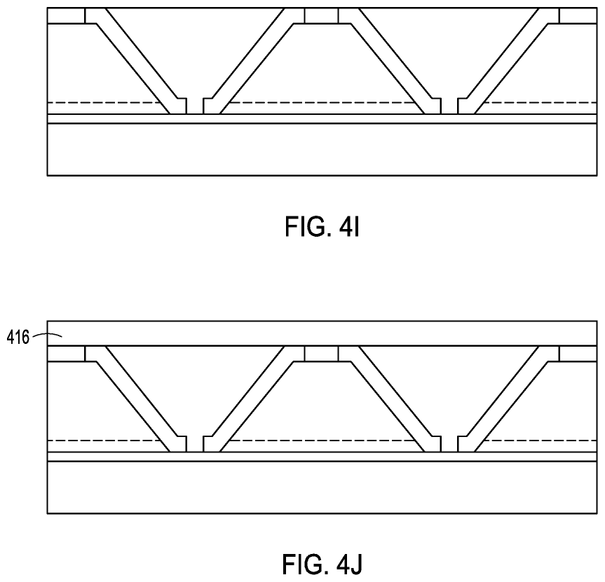

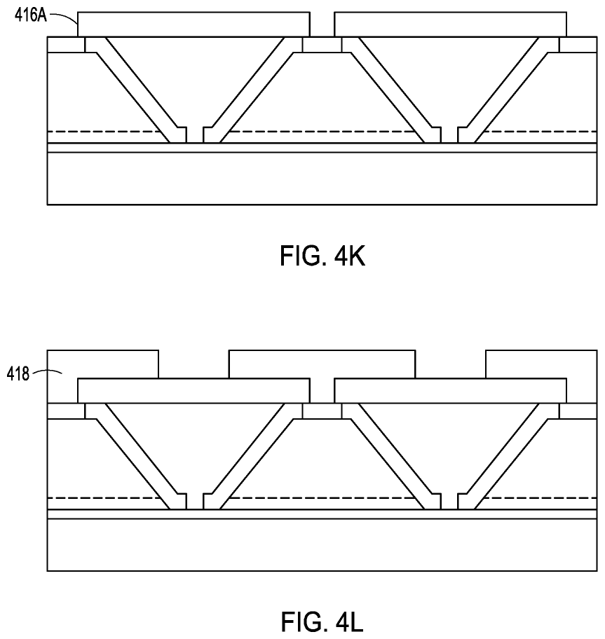

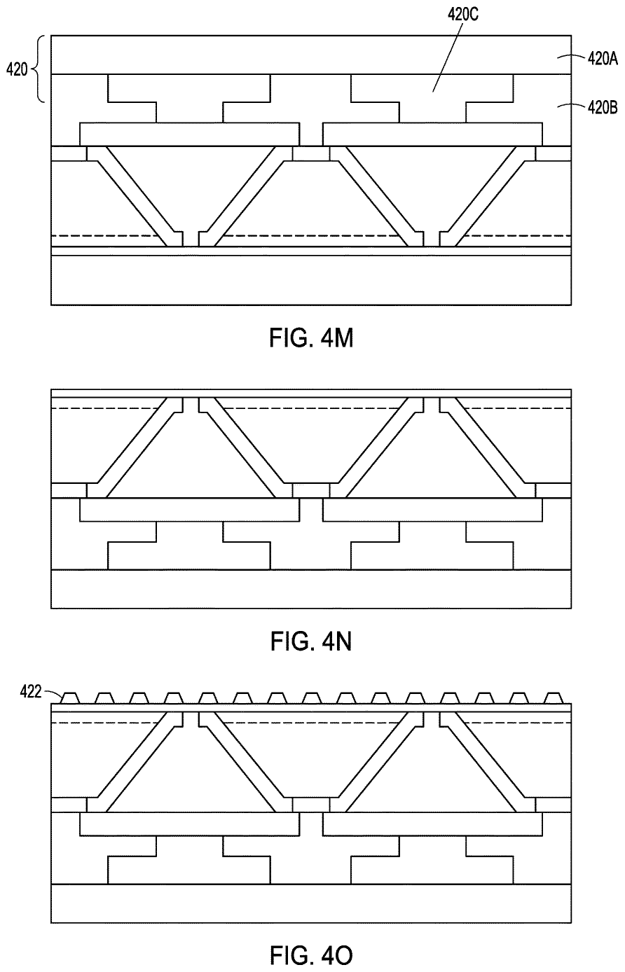

In FIG. 3D, the epitaxial layer 304 is then further etched to form pixels 308 that have a trapezoidal shape. The angle of the slope of the sidewalls (θ) may be in the range of about 15° to about 35°, for example. To form the epitaxial layer 304, an angled photoresist may be used during the photolithographic processes. In some embodiments, a TCO layer may be used as an etch stop to limit the etching. In other cases, the TCO layer may be deposited in one or more subsequent steps. This is described in more detail with respect to FIGS. 4A-4O

In FIG. 3E, an insulating layer 310 is deposited on the pixels 308. The insulating layer 310 may be formed from SiO2 and/or one or more other insulating materials.

In FIG. 3F, openings 310a are created in the insulating layer 310. The openings 310a may be etched using photolithographic processes. The openings 310a may be formed at the apex of each of, as well as between, the pixels 308. The openings 310a expose portions of the n-type semiconductor layer 304a and the temporary substrate 306 underlying the insulating layer 310.

In FIG. 3G, a metal seed layer is deposited on the insulating layer 310 and openings 310a and metal plating 312 is deposited on the metal seed layer. The metal seed layer and metal plating 312 may be formed from Al, TiW, and/or Cu as above. As shown in FIG. 2D, in some embodiments, other conductive layers such as the guardsheet and the reflector metal may be deposited in the openings 310a prior to deposition of the metal plating 312.

In FIG. 3H, the metal plating 312 is planarized (e.g., through CMP) to electrically isolate portions of the metal plating 312 from each other. Specifically, as shown in FIG. 3H, the metal plating 312 deposited in openings 310a at the apex of the pixels 308 may be isolated from the metal plating 312 on the insulating layer 310 on the sidewalls of the pixels 308. The portions of the metal plating 312 may eventually form the anode and cathode contacts of the final LED structure.

In FIG. 3I, another insulating layer 314 is deposited on the metal plating 312 and the exposed insulating layer 310 between the isolated portions of the metal plating 312. The other insulating layer 314 may be formed from SiO2 and/or one or more other insulating materials similar to the insulating layer 310.

In FIG. 3J, openings 314a are created in the other insulating layer 314 to expose portions of the metal plating 312. As shown, the openings 314a in the other insulating layer 314 expose portions of the metal plating 312 deposited in openings 310a at the apex of the pixels 308.

In FIG. 3K, a bonding layer 316 is deposited and lithographically fabricated on the openings 314a to provide bonding pads that contact exposed portions of the metal plating 312.

In FIG. 3L, after the bonding layer 316 is deposited, the resulting structure is hybridized by attaching a CMOS backplane 318, Si submount, or other structure to operate the segmented array. The bonding layer 316 and the CMOS backplane 318 may have atomically smooth oxide layers. The CMOS backplane 318 may include a substrate 318a with contacts 318b that are separated by a dielectric layer 318c. The CMOS backplane 318 may include integrated circuitry disposed thereon, for example.

In FIG. 3M, the temporary substrate 306 may be removed (e.g., by wet or dry chemical etching, mechanical removal, or liftoff using a sacrificial layer) to expose the p-type semiconductor layer 304c and the metal plating 312 between the pixels 308. As noted above, a TCO layer 320, if not already present, may be sputtered on the p-type semiconductor layer 304c and the metal plating 312 between the pixels 308 exposed after removal of the temporary substrate 306.

In FIG. 3N, a periodic nanostructure 322 may be optically patterned on the TCO layer 320 using photolithographic processes. The periodic nanostructure 322 may be designed (e.g., via periodicity and shape) to adjust optical properties of the light emitted from the TCO layer 320. The periodic nanostructure 322 may be formed from an optically transparent, translucent, and/or opaque material, such as a metal or dielectric.

FIGS. 4A-4O illustrate another fabrication method for a p-side up microLED structure, in accordance with some examples. Similar materials may be used as those in FIGS. 3A-3N. FIG. 4A illustrates an initial structure 400 that includes an epitaxial layer 404 of thickness t (e.g., about 6 μm) grown on a Sapphire substrate 402. The epitaxial layer 404 may include a relatively thicker n-type semiconductor layer 404a and a relatively thinner p-type semiconductor layer 404c surrounding a MQW active layer 404b.

In FIG. 4B, a TCO layer 406 is sputtered on the p-type semiconductor layer 404c. As above, the TCO layer 406 may be formed from ITO.

In FIG. 4C, a temporary substrate 408 is attached to the TCO layer 406 using an adhesive or other technique.

In FIG. 4D, the (Sapphire) substrate 402 is removed and the n-type semiconductor layer 404a is etched such that the remaining epitaxial layer 404 has a thickness t′ significantly less than the original thickness (e.g., about 1-2 μm). In embodiments in which the doping of the n-type semiconductor layer varies with depth, the etching may expose a more heavily n-doped (n++) semiconductor layer.

In FIG. 4E, the epitaxial layer 404 may then be further etched to form trapezoidal pixels 410 and expose a portion of the TCO layer 406. The angle of the slope of the sidewalls (θ) may be greater than in the range of about 15° to about 35°. To form the epitaxial layer 404, an angled photoresist may be used during the photolithographic processes.

In FIG. 4F, an insulating layer 412 (or other dielectric/insulating layer) is deposited on the pixels 410 and also covers the exposed portion of the TCO layer 406. The insulating layer 412 may be formed from SiO2 and/or one or more other insulating materials.

In FIG. 4G, openings 412a are created in the insulating layer 412. The openings 412a may be etched using photolithographic processes. The openings 412a may be formed at the apex of each of, as well as between, the pixels 410. The openings 412a expose portions of the n-type semiconductor layer 404a and at least some of the exposed portion of the TCO layer 406.

In FIG. 4H, a metal seed layer and metal plating 414 are deposited on the insulating layer 412 and openings 412a. The metal seed layer and metal plating 414 may be formed from Al, TiW, and/or Cu as above. As shown in FIG. 2D, in some embodiments, other conductive layers such as the guardsheet and the reflector metal may be deposited in the openings 412a prior to deposition of the metal plating 414.

In FIG. 4I, the metal plating 414 is planarized (e.g., through CMP) to electrically isolate portions of the metal plating 414 from each other.

As shown, the metal plating 414 deposited in openings 412a at the apex of the pixels 410 may be isolated from the metal plating 414 on the insulating layer 412 on the sidewalls of the pixels 410. The portions of the metal plating 414 may eventually form the anode and cathode contacts of the final LED structure.

In FIG. 4J, another insulating layer 416 (or other dielectric/insulating layer) is deposited on the metal plating 414 (and the exposed portions of the insulating layer 412). The other insulating layer 416 may be formed from SiO2 and/or one or more other insulating materials, similar to the insulating layer 412.

In FIG. 4K, openings 416a are created in the other insulating layer 416 to expose portions of the metal plating 414. The openings 416a expose the metal plating 414 deposited in openings 412a at the apex of the pixels 410.

In FIG. 4L, a bonding layer 418 is deposited and lithographically fabricated on the openings 416a to provide bonding pads that contact exposed portions of the metal plating 414.

In FIG. 4M, after the bonding layer 418 is deposited, the resulting structure is hybridized by attaching a monolithic structure 420. The monolithic structure 420 may include a substrate 420a with contacts 420b that are separated by a dielectric 420c. The monolithic structure 420 may include integrated circuitry disposed thereon, for example.

In FIG. 4N, the temporary substrate 408 may be removed to expose the TCO layer 406.

In FIG. 4O, a periodic nanostructure 422 may be optically patterned on the TCO layer 406.

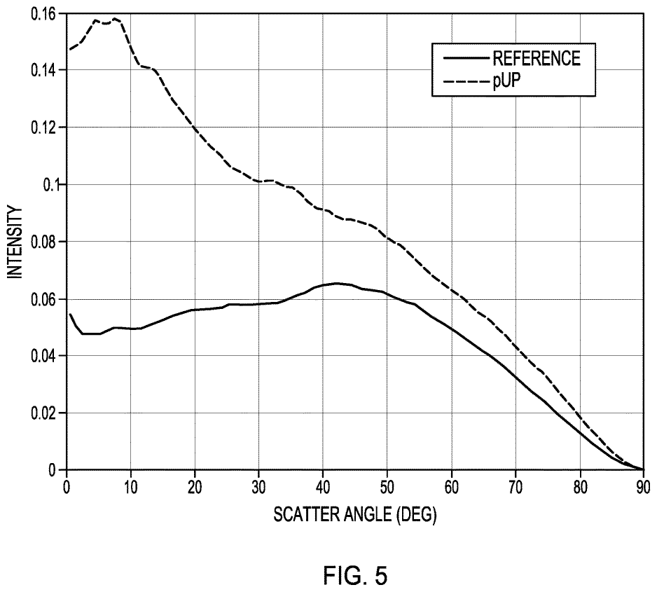

FIG. 5 shows a simulated performance comparison between LED structures. As shown, the pGaN up architecture provides an improved light extraction efficiency and directionality. As shown, the far-field angular emission response of FIG. 5 shows a simulated ExE gain of about 53% and a simulated on-axis intensity gain of about 300% between the embodiments shown in FIGS. 2C and 2D.

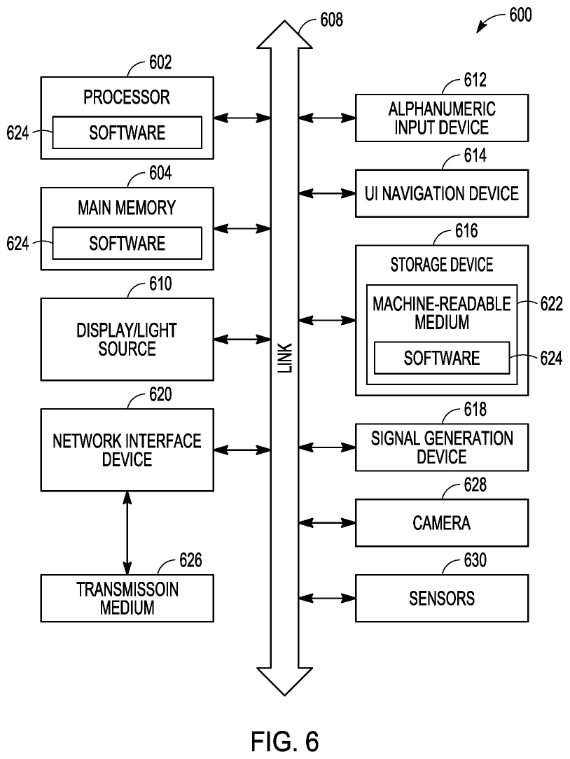

FIG. 6 illustrates an example of a general device in accordance with some embodiments. The device 600 may be a mobile device such as a laptop computer (PC), a tablet PC, a smart phone, or an augmented reality (AR)/virtual reality (VR), or an automotive device, for example. Various elements may be provided on the backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 600 may include a hardware processor (or equivalently processing circuitry) 602 (e.g., a central processing unit (CPU), a GPU, a hardware processor core, or any combination thereof), a memory 604 (which may include main and static memory), some or all of which may communicate with each other via an interlink (e.g., bus) 608. The memory 604 may contain any or all of removable storage and non-removable storage, volatile memory or non-volatile memory. The electronic device 600 may further include a display/light source 610 such as the LEDs described above, or a video display, an alphanumeric input device 612 (e.g., a keyboard), and a user interface (UI) navigation device 614 (e.g., a mouse). In an example, the display/light source 610, input device 612 and UI navigation device 614 may be a touch screen display. The electronic device 600 may additionally include a storage device (e.g., drive unit) 616, a signal generation device 618 (e.g., a speaker), a network interface device 620, one or more cameras 628, and one or more sensors 630, such as a global positioning system (GPS) sensor, compass, accelerometer, or other sensor such as those described herein. The electronic device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. The instructions 624 may also reside, completely or at least partially, within the memory 604 and/or within the hardware processor 602 during execution thereof by the electronic device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the electronic device 600 and that cause the electronic device 600 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols or a SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.16.4 family of standards, a Long Term Evolution (LTE) family of standards, a Universal Mobile Telecommunications System (UMTS) family of standards, peer-to-peer (P2P) networks, a next generation (NG)/6^{th} generation (6G) standards among others. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

The camera 628 may sense light at least the wavelength or wavelengths emitted by the LEDs. The camera 628 may include optics (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 602 may control and drive the LEDs via one or more drivers. For example, the processor 602 may optionally control one or more LEDs in LED arrays independent of another one or more LEDs in the LED arrays, so as to illuminate an area in a specified manner.

In addition, the sensors 630 may be incorporated in the camera 628 and/or the light source 610. The sensors 630 may sense visible and/or infrared light, and may further sense the ambient light and/or variations/flicker in the ambient light in addition to reception of the reflected light from the LEDs. The sensors may have one or more segments (that are able to sense the same wavelength/range of wavelengths or different wavelength/range of wavelengths), similar to the LED arrays.

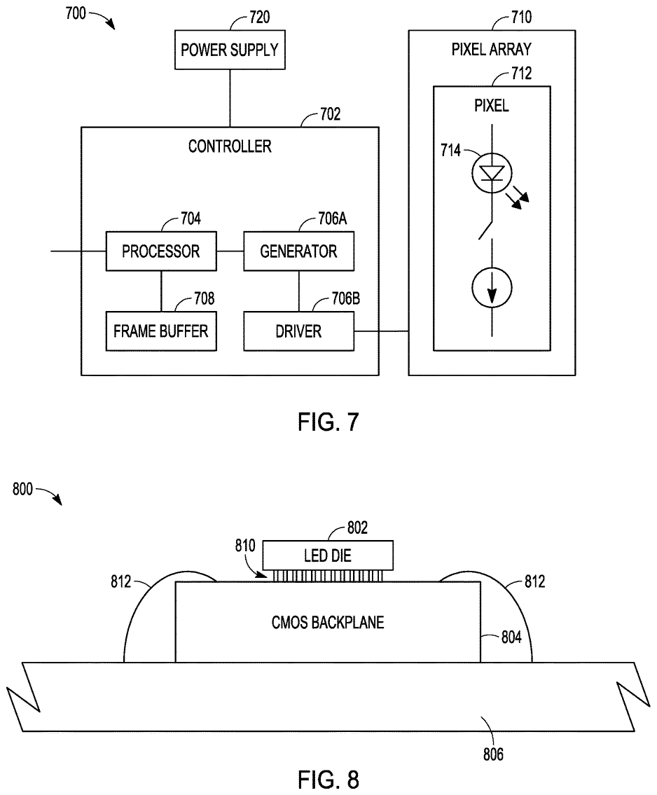

FIG. 7 illustrates an example lighting system, according to some embodiments. As above, some of the elements shown in the lighting system 700 may not be present, while other additional elements may be disposed in the lighting system 700. The lighting system 700 may include a controller 702 that controls illumination using a pixel array 710 that contains multiple individual pixels 712.

In some embodiments, some or all of the components described as the controller 702 may be disposed on a backplane such as, for example, a complementary metal oxide semiconductor (CMOS) backplane. The controller 702 may be coupled to or include one or more processors 704. The processor 704 may receive image data (in frames) via an interface and may process the image data to control a generator 706a, for example, controlling analog signals or PWM duty cycles and/or turn-on times for causing the lighting system 700 to produce the images indicated by the image data.

The controller 702 may further include a frame buffer 708. The frame buffer 708 may store one or more images prior the one or more processors 704 and store the indications for implementation by the one or more processors 704.

The generator 706a may be controlled by the processor 704 and may produce driving signals in accordance with the indications. The generator 706a may be connected to a driver 706b (such as that described in FIGS. 2A-2D) to drive the pixel array 710 so that the pixels 712 provide desired intensities of light.

Each pixel 712 may include one or more LEDs 714. The LEDs 714 may be different colors and may be controlled individually or in groups. As shown, the pixel 712 may include, for each pixel 712 or LED 714, a PWM switch, and a current source. The pixel 712 may be driven by the driver 706b. The signal from the generator 706a may cause the switch to open and close in accordance with the value of the signal. The signal corresponding to the intensities of light may cause the current source to produce a current flow to cause the pixels 712 to produce the corresponding intensities of light.

The lighting system 700 may further include a power supply 720. In some embodiments, the power supply 720 may be a battery that produces power for the controller 702.

FIG. 8 illustrates an example hardware arrangement for implementing the above disclosed subject matter, according to some embodiments. In particular, the hardware arrangement 800 may include an LED die 802 that contains the LED array(s) and a backplane, such as a CMOS backplane 804. The LED die 802 may be coupled to the CMOS backplane 804 by one or more interconnects 810, where the interconnects 810 may provide for transmission of signals between the LED die 802 and the CMOS backplane 804. The interconnects 810 may comprise one or more solder bump joints, one or more copper pillar bump joints, other types of interconnects known in the art, or some combination thereof.

The LED die 802 may include circuitry to implement the LED array described above. In particular, the LED die 802 may include a plurality of LEDs. The LED die 802 may include a shared active layer and a shared substrate for the LED array, and thereby the LED array may be a monolithic LED array. Each LED of the LED array may include an individual segmented active layer and/or substrate. In some embodiments, the LED die 802 may further include switches and current sources to drive the LED array as described above. In other embodiments, the switches and the current sources may be included in the CMOS backplane 804. The LEDs may be micro-LEDs or LEDs larger than micro-LEDs.

The CMOS backplane 804 may include circuitry to implement the control module. The CMOS backplane 804 may utilize the interconnects 810 to provide the LED array with the driving signals and the signals for the intensity for causing the LED array to produce light in accordance with the signals and the intensity.

The hardware arrangement 800 may further include a PCB 806. The PCB 806 may include circuitry to implement various functionality described herein. The PCB 806 may be coupled to the CMOS backplane 804. For example, the PCB 806 may be coupled to the CMOS backplane 804 via one or more wire bonds 812. The PCB 806 and the CMOS backplane 804 may exchange image data, power, and/or feedback via the coupling, among other signals.

As shown, the LEDs and circuitry supporting the LED array can be packaged and include a submount or printed circuit board for powering and controlling light production by the LEDs. The PCB supporting the LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the LED array and a power supply, and also provide heat sink functionality.

In general, a variety of applications may be supported by LED arrays. Such applications may include stand-alone applications to provide general illumination (e.g., within or external to a room or vehicle) or to provide specific images. In addition to devices such as a luminaire, projector, mobile device, the system may be used to provide AR and VR-based applications. Visualization systems, such as VR and AR systems, are becoming increasingly more common across numerous fields such as entertainment, education, medicine, and business. Various types of devices may be used to provide AR/VR to users, including headsets, glasses, and projectors. Such an AR/VR system may include components similar to those described above: the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more groups of LEDs to display content (AR/VR and/or non-AR/VR) to the user while controlling other LEDs and sensors used in eye tracking to adjust the content displayed. Content display LEDs may be designed to emit light within the visible band (approximately 400 nm to 780 nm) while LEDs used for tracking may be designed to emit light in the IR band (approximately 780 nm to 2,200 nm). In some embodiments, the tracking LEDs and content LEDs may be simultaneously active. In some embodiments, the tracking LEDs may be controlled to emit tracking light during a time period that content LEDs are deactivated and are thus not displaying content to the user. The AR/VR system can incorporate optics, such as those described above, and/or an AR/VR display, for example to couple light emitted by LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in the three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

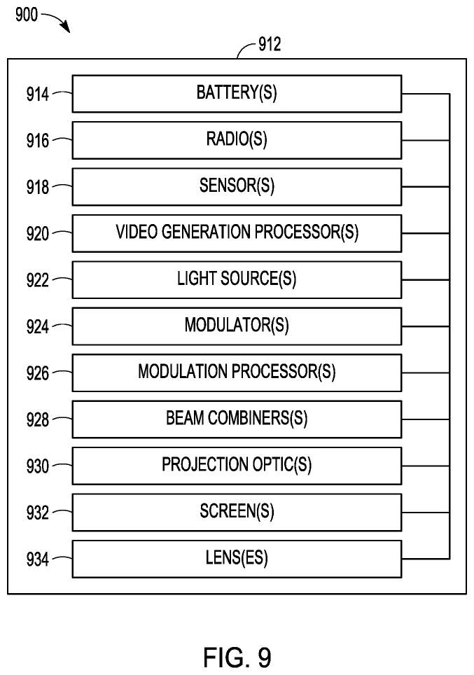

FIG. 9 shows a block diagram of an example of a system, according to some embodiments. The system 900 may provide AR/VR functionality using microLEDs. The system 900 can include a wearable housing 912, such as a headset or goggles. The housing 912 can mechanically support and house the elements detailed below. In some examples, one or more of the elements detailed below can be included in one or more additional housings that can be separate from the wearable housing 912 and couplable to the wearable housing 912 wirelessly and/or via a wired connection. For example, a separate housing can reduce the weight of wearable goggles, such as by including batteries, radios, and other elements. The housing 912 can include one or more batteries 914, which can electrically power any or all of the elements detailed below. The housing 912 can include circuitry that can electrically couple to an external power supply, such as a wall outlet, to recharge the batteries 914. The housing 912 can include one or more radios 916 to communicate wirelessly with a server or network via a suitable protocol, such as WiFi.

The system 900 can include one or more sensors 918, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 918 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 918 can capture a real-time video image of the surroundings proximate a user.

The system 900 can include one or more video generation processors 920. The one or more video generation processors 920 can receive scene data that represents a three-dimensional scene, such as a set of position coordinates for objects in the scene or a depth map of the scene. This data may be received from a server and/or a storage medium. The one or more video generation processors 920 can receive one or more sensor signals from the one or more sensors 918. In response to the scene data, which represents the surroundings, and at least one sensor signal, which represents the location and/or orientation of the user with respect to the surroundings, the one or more video generation processors 920 can generate at least one video signal that corresponds to a view of the scene. In some examples, the one or more video generation processors 920 can generate two video signals, one for each eye of the user, that represent a view of the scene from a point of view of the left eye and the right eye of the user, respectively. In some examples, the one or more video generation processors 920 can generate more than two video signals and combine the video signals to provide one video signal for both eyes, two video signals for the two eyes, or other combinations.

The system 900 can include one or more light sources 922 that can provide light for a display of the system 900. Suitable light sources 922 can include the microLEDs above, for example. The one or more light sources 922 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The system 900 can include one or more modulators 924. The modulators 924 can be implemented in one of at least two configurations. In a first configuration, the modulators 924 can include circuitry that can modulate the light sources 922 directly. For example, the light sources 922 can include an array of light-emitting diodes, and the modulators 924 can directly modulate the electrical power, electrical voltage, and/or electrical current directed to each light-emitting diode in the array to form modulated light. The modulation can be performed in an analog manner and/or a digital manner. In some examples, the light sources 922 can include an array of red light-emitting diodes, an array of green light-emitting diodes, and an array of blue light-emitting diodes, and the modulators 924 can directly modulate the red light-emitting diodes, the green light-emitting diodes, and the blue light-emitting diodes to form the modulated light to produce a specified image.

In a second configuration, the modulators 924 can include a modulation panel, such as a liquid crystal panel. The light sources 922 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 924 can include multiple modulation panels that can modulate different colors of light. For example, the modulators 924 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 924 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The system 900 can include one or more modulation processors 926, which can receive a video signal, such as from the one or more video generation processors 920, and, in response, can produce an electrical modulation signal. For configurations in which the modulators 924 directly modulate the light sources 922, the electrical modulation signal can drive the modulators 924. For configurations in which the modulators 924 include a modulation panel, the electrical modulation signal can drive the modulation panel.

The system 900 can include one or more beam combiners 928 (also known as beam splitters), which can combine light beams of different colors to form a single multi-color beam. For configurations in which the light sources 922 can include multiple light-emitting diodes of different colors, the system 900 can include one or more wavelength-sensitive (e.g., dichroic) beam combiners 928 that can combine the light of different colors to form a single multi-color beam.

The system 900 can direct the modulated light toward the eyes of the viewer in one of at least two configurations. In a first configuration, the system 900 can function as a projector, and can include suitable projection optics 930 that can project the modulated light onto one or more screens 932. The screens 932 can be located a suitable distance from an eye of the user. The system 900 can optionally include one or more lenses 934 that can locate a virtual image of a screen 932 at a suitable distance from the eye, such as a close-focus distance, such as 500 mm, 750 mm, or another suitable distance. In some examples, the system 900 can include a single screen 932, such that the modulated light can be directed toward both eyes of the user. In some examples, the system 900 can include two screens 932, such that the modulated light from each screen 932 can be directed toward a respective eye of the user. In some examples, the system 900 can include more than two screens 932. In a second configuration, the system 900 can direct the modulated light directly into one or both eyes of a viewer. For example, the projection optics 930 can form an image on a retina of an eye of the user, or an image on each retina of the two eyes of the user.

For some configurations of AR systems, the system 900 can include at least a partially transparent display, such that a user can view the user's surroundings through the display. For such configurations, the AR system can produce modulated light that corresponds to the augmentation of the surroundings, rather than the surroundings itself. For example, in the example of a retailer showing a chair, the AR system can direct modulated light, corresponding to the chair but not the rest of the room, toward a screen or toward an eye of a user.

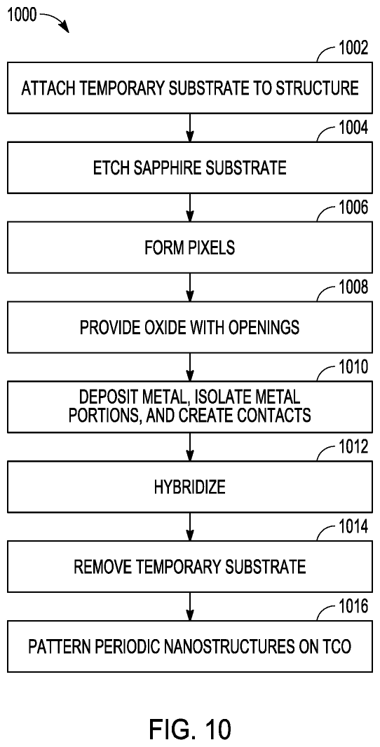

FIG. 10 illustrates an example method of fabricating an illumination device, according to some embodiments. Not all of the operations may be undertaken in the method 1000, and/or additional operations may be present. The operations may occur in a different order from that indicated in FIG. 10.

At operation 1002, a temporary substrate is attached to an initial structure that includes a Sapphire substrate and epitaxial layer (including n-type semiconductor layer, p-type semiconductor layer and active region). If a TCO layer may have been deposited on the initial structure, the temporary substrate is attached to the TCO layer.

At operation 1004, the Sapphire substrate is etched or otherwise removed and the n-type semiconductor layer is etched such that the remaining epitaxial layer has a thickness significantly less than the thickness of the initial structure.

At operation 1006, the epitaxial layer is formed into trapezoidal pixels via etching.

At operation 1008, an oxide layer is deposited on the pixels, which is then etched to expose the n-type semiconductor layer at the top of the pixel, as well as the temporary substrate or TCO layer.

At operation 1010, a metal seed layer and metal plating are deposited on the oxide layer and openings and etched to electrically isolate portions of the metal plating. Another oxide layer is deposited on the metal plating, openings are etched to expose portions of the metal plating, and a bonding layer is deposited and fabricated on the openings to provide bonding pads that contact exposed portions of the metal plating.

At operation 1012, the resulting structure is hybridized by attaching a monolithic structure to the bonding pads.

At operation 1014, the temporary substrate removed from the hybridized structure.

At operation 1016, a periodic nanostructure is patterned on the TCO layer, which may be deposited after removal of the temporary substrate if not already present.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

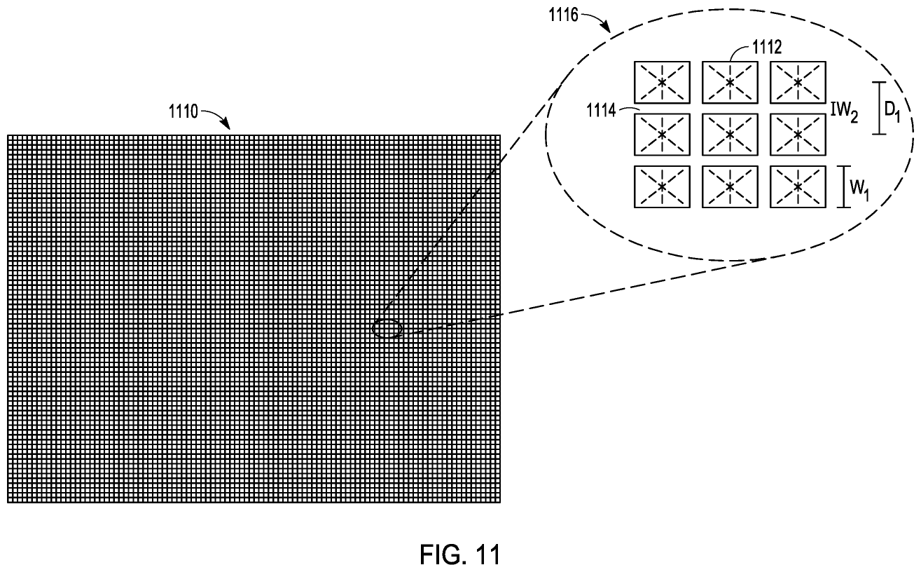

FIG. 11 illustrates a top plan view of an example array suitable for implementing embodiments described herein. The example hybridized device illustrated in FIG. 11 includes an LED die 1110 that includes LEDs 1112, such as those described herein. Projected patterned light may define images that may include light emitted from the LEDs 1112. Each LED 1112 (or group of LEDs) of the array may correspond to a projector picture element or projector pixel. In embodiments described herein, the LEDs 1112. Suitable hybridized devices may include monolithic LED arrays, micro LED arrays, etc. Each LED 1112 in LED die 1110 may be individually addressable. Alternatively, groups or subsets of LEDs 1112 may be addressable. In embodiments described herein, each array may comprise micro LEDs. Each LED 1112 may have a size in the range of micrometers (i.e., between 1 micrometer (μm) and 100 μm). For example, LED 1112 may have dimensions of approximately (within 10 μm by 10 μm) 40 μm by 40 μm in some embodiments. An LED 1112 may have a lateral dimension of less than 100 μm in some embodiments.

LEDs 1112 may be arranged as a matrix comprising one or more rows and one or more columns to define a rectangle. In other embodiments, LEDs 1112 may be arranged to define other shapes. Each micro-LED included in the LED die 1110 may encompass thousands or millions of projector pixels or LEDs. For example, an LED die 1110 that contains a μLED may include within 5,000 pixels, 20,000 pixels or more-such as millions of pixels. Each pixel may include an emitter. An LED die 1110 that contains the μLED can support high-density pixels having a lateral dimension less than 150 μm by 150 μm. In some embodiments, a μLED die can have dimensions of about 50 μm in diameter or width. In some embodiments, the height dimension of an array including the LEDs 1112, their supporting substrate and electrical traces, and associated micro-optics may be less than 5 millimeters.

An exploded view of a 3×3 sub-array 1116 of LEDs 1112 included in LED die 1110 is also shown in FIG. 11. Sub-array 1116 may include LEDs 1112, each defined by a width w1. In some example embodiments, width w1 can be approximately 100 μm or less (e.g., 40 μm). As shown in the sub-array 1116, lanes 1114 may be defined extending horizontally and vertically to define rows and columns of LEDs 1112. Lanes 1114 between the LEDs 1112 may have a width, w2, wide. In some embodiments, the width w2 may be approximately 20 μm or less (e.g., 5 μm). In some embodiments, the width w2 may be as small as 1 μm. The lanes 1114 may provide an air gap between adjacent emitters or may contain other material. A distance d1 from the center of one LED 1112 to the center of an adjacent LED 1112 may be approximately 120 μm or less (e.g., 45 μm). It will be understood that the widths and distances provided herein are examples of one of many possible embodiments in which widths and/or other dimensions may vary.

In some example embodiments, lanes 1114 may be defined by a width w2 that can be approximately 20 μm or less (e.g., 5 μm). In some example embodiments, width w2 can be as small as 1 μm. Lanes 1114 can serve to provide an air gap between adjacent LEDs 1112 and may contain material other than light emitting material. In some example embodiments, a distance d1 from the center of one LED 1112 to the center of an adjacent LED 1112 can be approximately 120 μm or less (e.g., 45 μm). It will be understood that the LED and lane widths and distances between LEDs are intended as examples. Persons of ordinary skill reading the disclosure herein will appreciate a range of widths and/or dimensions will be suitable for various implementations, and those embodiments will fall within the scope of the disclosure.

For the convenience of illustration, LED 1112 that are included in the LED die 1110 are depicted herein as having a rectangular shape. However, as persons of ordinary skill will appreciate, a variety of other emitter shapes would be suitable for implementing the LED 1112 and LED die 1110 in various applications, and those would fall within the scope of the embodiments described herein. Likewise, LED die 1110 is depicted in FIG. 11 as a symmetric matrix of LEDs 1112 (and/or other emitters). However, various other implementations of the LED die 1110 may be suitable for implementing embodiments described herein, depending on application and design considerations. For example, in some implementations, LED die 1110 can comprise a linear array of LED 1112, and in other implementations a rectangular array of LEDs 1112. In some implementations, the LED die 1110 can comprise a symmetric or asymmetric matrix of LEDs 1112. LED die 1110 can comprise an array or matrix defined by a dimension or order that differs from the array dimensions or orders depicted herein.

For example, in some practical applications, the LED die 1110 depicted in FIG. 11 may include over 20,000 LEDs 1112 in asymmetric or symmetric arrangements in a wide range of array dimensions and orders (e.g., a 200×100 array, a symmetric matrix, or a non-symmetric matrix). For example, in some practical applications, two or more LED dies 1110 can be stacked such that LEDs 1112 are arranged to define rows and columns that extend in three spatial directions or dimensions. It will also be understood that the LED die 1110 can itself be a subarray of a larger array (not shown) of LEDs 1112.

LED die 1110 may have a surface area of 90 mm² or greater and may require significant power to drive the array. In some applications, this power can be as much as 60 watts or more. The LED die 1110 may include hundreds, thousands, or even millions of LEDs or emitters arranged within a centimeter-scale area substrate or smaller. A micro LED may include an array of individual emitters provided on a substrate or may be a single silicon wafer, or die partially or fully divided into light-emitting segments that form the LEDs 1112. In some embodiments, the emitters may have distinct non-white colors. For example, at least four of the emitters may be RGBY groupings of emitters.

### EXAMPLES

Example 1 is a method of fabricating a light emitting diode (LED) array, the method comprising: etching an n-type semiconductor layer of an epitaxial LED structure that contains the n-type semiconductor layer, a p-type semiconductor layer, and an active region between the n-type semiconductor layer and the p-type semiconductor layer, the active region configured to emit light from the LED array through the p-type semiconductor layer; forming pixels in the epitaxial LED structure after the etching, the pixels having a trapezoidal cross-section with respect to a growth direction of the epitaxial LED structure; forming contacts to the n-type semiconductor layer and the p-type semiconductor layer; and attaching a monolithic structure to the contacts to form a hybridized structure containing LEDs.

In Example 2, the subject matter of Example 1 includes, patterning a periodic nanostructure on a transparent conducting oxide (TCO) layer on the p-type semiconductor layer of the hybridized structure.

In Example 3, the subject matter of Example 2 includes, forming the TCO layer on the p-type semiconductor layer after forming the hybridized structure.

In Example 4, the subject matter of Examples 2-3 includes, forming the TCO layer on the p-type semiconductor layer before etching the n-type semiconductor layer.

In Example 5, the subject matter of Examples 1-4 includes, wherein the pixels are grown on a Sapphire substrate, the method further comprising: attaching a temporary substrate to the p-type semiconductor layer; and removing the Sapphire substrate from the epitaxial LED structure after attaching the temporary substrate prior to etching the n-type semiconductor layer.

In Example 6, the subject matter of Examples 1-5 includes, wherein forming the contacts comprises: forming a dielectric layer on the trapezoidal pixels; forming openings in the dielectric layer at an apex of the trapezoidal pixels and between the trapezoidal pixels; and forming a metal layer on the openings in the dielectric layer to isolate portions of the metal layer in each of the openings.

In Example 7, the subject matter of Example 6 includes, wherein forming the metal layer on the openings in the dielectric layer comprises plating the metal layer and etching back the metal layer after the plating to isolate the portions of the metal layer, the portions of the metal layer forming anode contacts and cathode contacts of the epitaxial LED structure.

In Example 8, the subject matter of Example 7 includes, wherein forming the contacts further comprises depositing another dielectric layer on the portions of the metal layer, etching openings in the other dielectric layer to expose at least some of the portions of the metal layer, and forming bonding pads to contact the at least some of the portions of the metal layer, at least a portion of the bonding pads disposed on the other dielectric layer.

In Example 9, the subject matter of Examples 1-8 includes, wherein sidewalls of the trapezoidal pixels extend at an angle of about 15° to about 35° from a direction of growth of the epitaxial LED structure.

In Example 10, the subject matter of Examples 1-9 includes, wherein each pixel has an area of about 25 μm² and a thickness of the epitaxial structure of about 1 μm to about 4 μm.

In Example 11, the subject matter of Examples 1-10 includes, wherein the LEDs are microLEDs.

Example 12 is a light emitting diode (LED) array comprising: a plurality of pixels, each pixel containing an epitaxial LED structure that comprises: an n-type semiconductor layer, a p-type semiconductor layer, and an active region between the n-type semiconductor layer and the p-type semiconductor layer, the pixel having a trapezoidal cross-section with respect to a growth direction of the epitaxial LED structure, and the active region configured to emit light from the LED array through the p-type semiconductor layer.

In Example 13, the subject matter of Example 12 includes, wherein sidewalls of the trapezoidal pixels extend at an angle of about 15° to about 35° from a direction of growth of the epitaxial LED structure.

In Example 14, the subject matter of Examples 12-13 includes, wherein the LEDs are microLEDs.

In Example 15, the subject matter of Examples 12-14 includes, a transparent conducting oxide (TCO) layer disposed on the p-type semiconductor layer; and a patterned periodic nanostructure on the TCO layer.

In Example 16, the subject matter of Examples 12-15 includes, a dielectric layer disposed on the trapezoidal pixels, the dielectric layer having openings at an apex of the trapezoidal pixels and between the trapezoidal pixels; and a metal layer disposed the openings, the metal layer forming isolated electrical contacts to the n-type semiconductor layer and the p-type semiconductor layer.

In Example 17, the subject matter of Example 16 includes, another dielectric layer disposed on the isolated electrical contacts, the other dielectric layer having openings that expose at least some of the isolated electrical contacts; and bonding pads that contact the at least some of portions of the metal layer, at least a portion of the bonding pads disposed on the other dielectric layer.

Example 18 is an electronic apparatus, comprising: a complementary metal oxide semiconductor (CMOS) backplane comprising: a light emitting diode (LED) array that comprises a plurality of trapezoidal pixels, each pixel containing an epitaxial LED structure that comprises: an n-type semiconductor layer, a p-type semiconductor layer, and an active region between the n-type semiconductor layer and the p-type semiconductor layer, the active region configured to emit light from the LED array through the p-type semiconductor layer, the pixels having a trapezoidal cross-section with respect to a growth direction of the epitaxial LED structure; and a controller configured to control the LED array.

In Example 19, the subject matter of Example 18 includes, wherein sidewalls of the trapezoidal pixels extend at an angle of about 15° to about 35° from a direction of growth of the epitaxial LED structure.

In Example 20, the subject matter of Examples 18-19 includes, wherein the LEDs are microLEDs that are individually controllable by the controller.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A method of fabricating a light emitting diode (LED) array, the method comprising:
etching an n-type semiconductor layer of an epitaxial LED structure that contains the n-type semiconductor layer, a p-type semiconductor layer, and an active region between the n-type semiconductor layer and the p-type semiconductor layer, the active region configured to emit light from the LED array through the p-type semiconductor layer;
forming pixels in the epitaxial LED structure after the etching, the pixels having a trapezoidal cross-section with respect to a growth direction of the epitaxial LED structure;
forming electrical contacts to the n-type semiconductor layer and the p-type semiconductor layer; and
attaching a monolithic structure to the contacts to form a hybridized structure containing LEDS,
wherein forming the electrical contacts to the n-type semiconductor layer comprises:
depositing a reflector metal layer in contact with the n-type semiconductor layer,
depositing a metal guardsheet on the reflector metal layer, the metal guardsheet configured to protect the reflector metal during subsequent processing and to provide electrical contact to the n-type semiconductor layer through the reflector metal, and
forming additional metal and dielectric layers on the metal guardsheet during the subsequent processing.

2. The method of claim 1, further comprising patterning a periodic nanostructure on a transparent conducting oxide (TCO) layer on the p-type semiconductor layer of the hybridized structure.

3. The method of claim 2, further comprising forming the TCO layer on the p-type semiconductor layer after forming the hybridized structure.

4. The method of claim 2, further comprising forming the TCO layer on the p-type semiconductor layer before etching the n-type semiconductor layer.

5. The method of claim 1, wherein the pixels are grown on a Sapphire substrate, the method further comprising:
attaching a temporary substrate to the p-type semiconductor layer; and
removing the Sapphire substrate from the epitaxial LED structure after attaching the temporary substrate prior to etching the n-type semiconductor layer.

6. The method of claim 1, wherein forming the contacts comprises:
forming a dielectric layer on the trapezoidal pixels;
forming openings in the dielectric layer at an apex of the trapezoidal pixels and between the trapezoidal pixels; and
forming a metal layer on the openings in the dielectric layer to isolate portions of the metal layer in each of the openings.

7. The method of claim 6, wherein forming the metal layer on the openings in the dielectric layer comprises plating the metal layer and etching back the metal layer after the plating to isolate the portions of the metal layer, the portions of the metal layer forming anode contacts and cathode contacts of the epitaxial LED structure.

8. The method of claim 7, wherein forming the contacts further comprises:
depositing another dielectric layer on the portions of the metal layer, etching openings in the other dielectric layer to expose at least some of the portions of the metal layer; and
forming bonding pads to contact the at least some of the portions of the metal layer, at least a portion of the bonding pads disposed on the other dielectric layer.

9. The method of claim 1, wherein sidewalls of the trapezoidal pixels extend at an angle of about 15° to about 35° from a direction of growth of the epitaxial LED structure.

10. The method of claim 1, wherein each pixel has an area of about 25 μm² and a thickness of the epitaxial structure of about 1 μm to about 4 μm.

11. The method of claim 1, wherein the LEDs are microLEDs.

12. A light emitting diode (LED) array comprising:
a plurality of pixels, each pixel containing an LED having an epitaxial LED structure that comprises:
an n-type semiconductor layer,
a p-type semiconductor layer, and
an active region between the n-type semiconductor layer and the p-type semiconductor layer,
the pixel having a trapezoidal cross-section with respect to a growth direction of the epitaxial LED structure, and
the active region configured to emit light from the LED array through the p-type semiconductor layer,
wherein electrical contacts on the n-type semiconductor layer include:
a reflector metal layer in contact with the n-type semiconductor layer,
a metal guardsheet on the reflector metal layer, and
additional metal and dielectric layers on the metal guardsheet.

13. The LED array of claim 12, wherein sidewalls of the trapezoidal pixels extend at an angle of about 15° to about 35° from a direction of growth of the epitaxial LED structure.

14. The LED array of claim 12, wherein the LEDs are microLEDs.

15. The LED array of claim 12, further comprising:
a transparent conducting oxide (TCO) layer disposed on the p-type semiconductor layer; and
a patterned periodic nanostructure on the TCO layer.

16. The LED array of claim 12, further comprising:
a dielectric layer disposed on the trapezoidal pixels, the dielectric layer having openings at an apex of the trapezoidal pixels and between the trapezoidal pixels; and
a metal layer disposed the openings, the metal layer forming isolated electrical contacts to the n-type semiconductor layer and the p-type semiconductor layer.

17. The LED array of claim 16, further comprising:
another dielectric layer disposed on the isolated electrical contacts, the other dielectric layer having openings that expose at least some of the isolated electrical contacts; and
bonding pads that contact the at least some of portions of the metal layer, at least a portion of the bonding pads disposed on the other dielectric layer.

18. An electronic apparatus, comprising:
a complementary metal oxide semiconductor (CMOS) backplane comprising:
a light emitting diode (LED) array that comprises a plurality of trapezoidal pixels, each pixel containing an LED having an epitaxial LED structure that comprises: an n-type semiconductor layer, a p-type semiconductor layer, and an active region between the n-type semiconductor layer and the p-type semiconductor layer, the active region configured to emit light from the LED array through the p-type semiconductor layer, the pixels having a trapezoidal cross-section with respect to a growth direction of the epitaxial LED structure; and
a controller configured to control the LED array,
wherein electrical contacts on the n-type semiconductor layer include:
a reflector metal layer in contact with the n-type semiconductor layer,
a metal guardsheet on the reflector metal layer, and
additional metal and dielectric layers on the metal guardsheet.

19. The electronic apparatus of claim 18, wherein sidewalls of the trapezoidal pixels extend at an angle of about 15° to about 35° from a direction of growth of the epitaxial LED structure.

20. The electronic apparatus of claim 18 wherein the LEDs are microLEDs that are individually controllable by the controller.
